(19) United States
(12) Patent Application Publication
(10) Pub. No.: US 2023/0395635 A1
(43) Pub. Date: Dec. 7, 2023

(54) IMAGE SENSOR

(71) Applicant: SAMSUNG ELECTRONICS CO., LTD., Suwon-si (KR)

(72) Inventors: Dong Min Han, Suwon-si (KR); Seung Joo Nah, Suwon-si (KR); Hee Geun Jeong, Suwon-si (KR)

(73) Assignee: SAMSUNG ELECTRONICS CO., LTD., Suwon-si (KR)

(21) Appl. No.: 18/204,783

(22) Filed: Jun. 1, 2023

(30) Foreign Application Priority Data
Jun. 2, 2022 (KR) 10-2022-0067549

(51) Int. Cl. H01L 27/146; H04N 25/79

(52) U.S. Cl. CPC H01L 27/14636; H04N 25/79; H01L 27/14645; H01L 27/14621; H01L 27/14627; H01L 27/1463; H01L 27/14634; H01L 27/1464; H01L 27/14689; H01L 27/1469

(57) ABSTRACT

An image sensor includes a first substrate including a first surface and a second surface opposite to the first surface, a first wiring structure provided on the second surface of the first substrate, the first wiring structure including a first wiring and a first inter-wiring insulating film, a second substrate including a third surface facing the second surface of the first substrate, and a fourth surface opposite to the third surface, a second wiring structure provided on the third surface of the second substrate, the second wiring structure including a second wiring and a second inter-wiring insulating film, a via trench penetrating the first substrate and the first wiring structure, a through via structure extending along the via trench and connected to the second wiring, and a pad pattern provided on the through via.

### CROSS-REFERENCE TO RELATED APPLICATION

This application is based on and claims priority to Korean Patent Application No. 10-2022-0067549 filed on Jun. 2, 2022 in the Korean Intellectual Property Office, the disclosure of which is incorporated herein by reference in its entirety.

### BACKGROUND

### 1. Field

The present disclosure relates to an image sensor.

### 2. Description of the Related Art

An image sensor is a type of semiconductor device that converts optical information into electrical signals. Examples of the image sensor include a charge-coupled device (CCD) image sensor and a complementary metal-oxide semiconductor (CMOS)-type image sensor.

Image sensors may be configured in the form of a package, and the package may be configured to be able to protect the image sensors and allow light to be incident upon the light-receiving areas or sensing areas of the image sensors.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public,

### SUMMARY

One or more example embodiments provide an image sensor with an improved product reliability.

Additional aspects will be set forth in part in the description which follows and, in part, will be apparent from the description, or may be learned by practice of the presented embodiments

According to an aspect of an example embodiments, an image sensor may include a first substrate including a first surface and a second surface opposite to the first surface, a first wiring structure provided on the second surface of the first substrate, the first wiring structure including a first wiring and a first inter-wiring insulating film, a second substrate including a third surface facing the second surface of the first substrate, and a fourth surface opposite to the third surface, a second wiring structure provided on the third surface of the second substrate, the second wiring structure including a second wiring and a second inter-wiring insulating film, a via trench penetrating the first substrate and the first wiring structure, a through via structure extending along the via trench and connected to the second wiring, and a pad pattern provided on the through via and filling at least a portion of the via trench.

According to an aspect of an example embodiment, an image sensor may include a first substrate including a first surface and a second surface opposite to the first surface, a first wiring structure provided on the second surface of the first substrate, the first wiring structure including a first wiring and a first inter-wiring insulating film, a second substrate including a third surface facing the second surface, and a fourth surface opposite to the third surface, a second wiring structure provided on the third surface of the second substrate, the second wiring structure including a second wiring and a second inter-wiring insulating film, a pad pattern including a first portion provided in the first wiring structure and the first substrate and a second portion provided in the first substrate on the first portion, the second portion having a width greater than a width of the first portion, and a through via structure extending from the first surface of the first substrate along at least a portion of the pad pattern and connected to the second wiring.

According to an aspect of an example embodiment, an image sensor that includes a pixel array area, a light-blocking area around the pixel array area, and pad regions around the pixel array area, may include a first substrate including a first surface and a second surface opposite to the first surface, pixel isolation patterns provided in the first substrate in the pixel array area and the light-blocking area, extending from the second surface, and defining a plurality of unit pixels, a plurality of microlenses provided on the first surface of the first substrate and respectively corresponding to the plurality of unit pixels, a first wiring structure provided on the second surface of the first substrate and including a first wiring and a first inter-wiring insulating film, a second substrate including a third surface facing the second surface of the first substrate, and a fourth surface opposite to the third surface, a second wiring structure provided on the third surface of the second substrate and including a second wiring and a second inter-wiring insulating film, a via trench provided in the pad regions and penetrating the first substrate and the first wiring structure, in the pad regions, such that at least a portion of the second wiring is exposed, a through via structure extending along the via trench, a pad pattern provided in the via trench and on the through via structure, and insulating patterns provided in the pad regions, spaced apart from the through via structure, and extending from the first surface of the first substrate.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a block diagram of an image sensing device according to example embodiments of the present disclosure;

FIG. 2 is a diagram of an image sensor according to example embodiments of the present disclosure;

FIG. 3 is a diagram of an image sensor according to example embodiments of the present disclosure;

FIGS. 4, 5, 6 and 7 are cross-sectional views taken along lines A-A′, B-B′, C-C′, and D-D′ of FIG. 3 according to example embodiments of the present disclosure;

FIG. 8 is a diagram of an image sensor according to example embodiments of the present disclosure;

FIGS. 9, 10 and 11 are cross-sectional views of an image sensor according to example embodiments of the present disclosure; and

FIGS. 12, 13, 14, 15, 16, 17, 18 and 19 are cross-sectional views illustrating a method of fabricating an image sensor according to example embodiments of the present disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

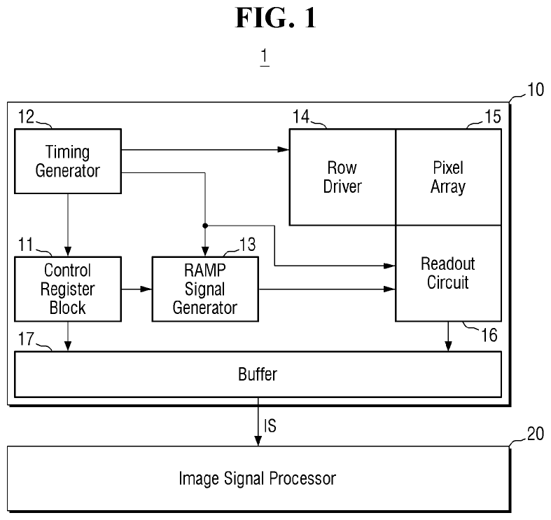

FIG. 1 is a block diagram of an image sensing device according to example embodiments of the present disclosure.

Referring to FIG. 1, an image sensing device 1 may include an image sensor 10 and an image signal processor 20.

The image sensor 10 may generate an image signal IS by sensing an image of a target object using light. In example embodiments, the image signal IS may be, for example, a digital signal, but the present disclosure is not limited thereto.

The image signal IS may be provided to, and processed by, the image signal processor 20. The image signal processor 20 may receive the image signal IS from a buffer 17 of the image sensor 10 and may process the image signal IS so that the image signal IS may be suitable to be displayed.

In example embodiments, the image signal processor 20 may perform digital binning on the image signal IS output from the image sensor 10. The image signal IS output from the image sensor 10 may be a raw image signal from a pixel array 15 that is yet to be subjected to analog binning or an image signal IS that has already been subjected to analog binning.

In example embodiments, the image sensor 10 and the image signal processor may be separate. For example, the image sensor 10 may be mounted in a first chip, the image signal processor 20 may be mounted in a second chip, and the image sensor 10 and the image signal processor 20 may communicate with each other via a predetermined interface. However, the present disclosure is not limited to this example. Alternatively, the image sensor 10 and the image signal processor 20 may be incorporated into a single package, for example, a multichip package (MCP).

The image sensor 10 may include the pixel array 15, a control register block 11, a timing generator 12, a row driver 14, a readout circuit 16, a ramp signal generator 13, and a buffer 17.

The control register block 11 may generally control the operation of the image sensor 10. The control register block 11 may transmit operation signals directly to the timing generator 12, the ramp signal generator 13, and the buffer 17.

The timing generator 12 may generate an operation timing reference signal that may be referenced for the operation of various elements of the image sensor 10. The operation timing reference signal may be transmitted to the ramp signal generator 13, the row driver 14, and the readout circuit 16.

The ramp signal generator 13 may generate and transmit ramp signals for use in the readout circuit 16. For example, the readout circuit 16 may include a correlated double sampler (CDS) and a comparator, and the ramp signal generator 13 may generate and transmit ramp signals for use in the CDS and the comparator.

The row driver 14 may selectively activate each row of the pixel array 15.

The pixel array 15 may sense an external image. The pixel array 15 may include a plurality of pixels (or unit pixels).

The readout circuit 16 may sample a pixel signal provided from the pixel array 15, may compare the pixel signal with a ramp signal, and may convert an analog image signal (or data) into a digital image signal (or data) based on the result of the comparison.

The buffer 17 may include, for example, a latch. The buffer 17 may temporarily store the image signal IS and may transmit the image signal IS to an external memory or an external device.

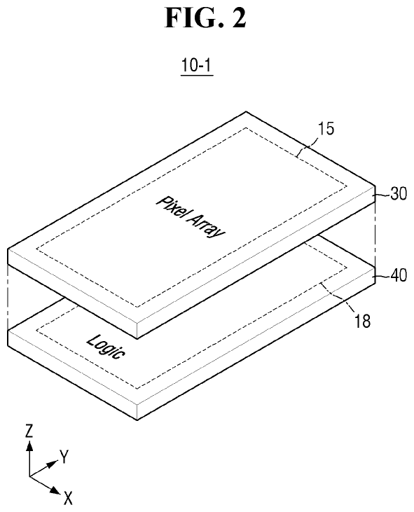

FIG. 2 is a diagram of an image sensor according to example embodiments of the present disclosure.

Referring to FIG. 2, an image sensor 10-1 may include a first layer 30 and a second layer 40. The second layer 40 and the first layer 30 may be stacked in a third direction Z and may be electrically connected.

The first layer 30 may include a pixel array 15, in which a plurality of pixels are arranged into a 2D array structure. The pixel array 15 may correspond to the pixel array 15 of FIG. 1.

The second layer 40 may include a logic area 18 where logic elements are disposed. The logic elements included in the logic area 18 may be electrically connected to the pixel array 15 and may provide signals to the pixels of the pixel array 15 or process signals output from the pixels of the pixel array 15. The logic area 18 may include, for example, the control register block 11, the timing generator 12, the ramp signal generator 13, the row driver 14, the readout circuit 16, and the buffer 17 of FIG. 1.

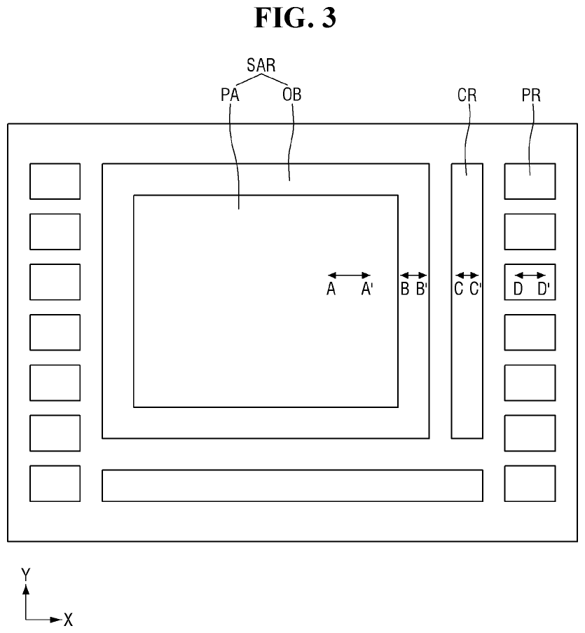

FIG. 3 is a diagram of an image sensor according to example embodiments of the present disclosure.

Referring to FIG. 3, the image sensor according to example embodiments of the present disclosure may include a sensor array region SAR, a connecting region CR, and pad regions PR.

The sensor array region SAR may include a pixel array area PA, which may correspond to the pixel array 15 of FIG. 1. The sensor array region SAR may include the pixel array area PA and a light-blocking area OB. In the pixel array area PA, active pixels, which receive light and generate active signals, may be arranged. In the light-blocking area OB, optical black pixels, which are not reached by light and generate optical black signals, may be arranged. The light-blocking area OB may be disposed around, for example, the pixel array area PA, but the present disclosure is not limited thereto. In example embodiments, dummy pixels may be further disposed in part of the pixel array area PA adjacent to the light-blocking area OB.

The connecting region CR may be disposed around the sensor array region SAR. The connecting region CR may be disposed on one side of the sensor array region SAR, but the present disclosure is not limited thereto. Lines may be disposed in the connecting region CR and may be configured to transmit electrical signals to, or receive electrical signals from, the sensor array region SAR.

The pad regions PR may be disposed around the sensor array region SAR. The pad regions PR may be disposed along the edges of the image sensor according to example embodiments of the present disclosure, but the present disclosure is not limited thereto. The pad regions PR may be connected to external devices and may be configured to transmit electrical signals between the image sensor according to example embodiments of the present disclosure and the external devices.

FIG. 3 illustrates that the connecting region CR is interposed between the sensor array region SAR and the pad regions PR, but the present disclosure is not limited thereto. The layout of the sensor array region SAR, the connecting region CR, and the pad regions PR may vary.

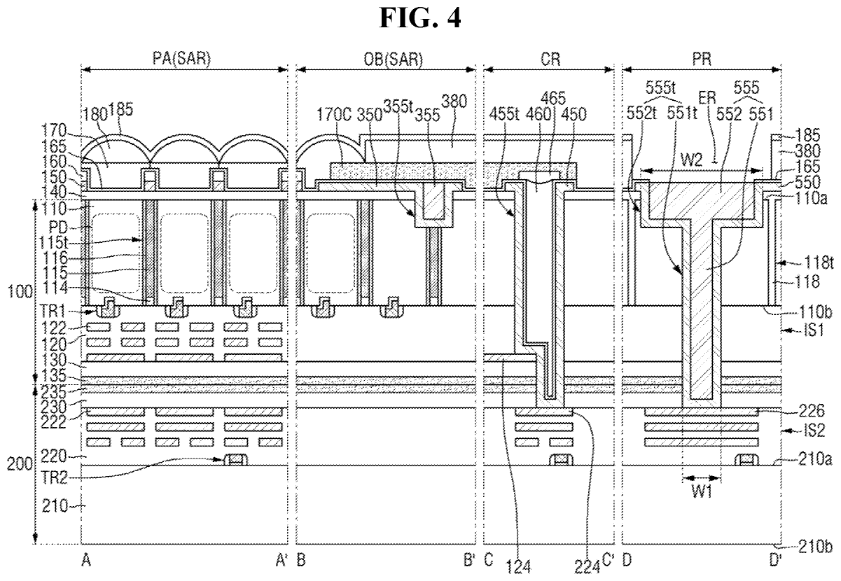

FIGS. 4, 5, 6 and 7 are cross-sectional views taken along lines A-A′, B-B′, C-C′, and D-D′ of FIG. 3 according to example embodiments of the present disclosure.

Referring to FIGS. 3 and 4, an image sensor according to example embodiments of the present disclosure includes a first substrate 110, a first wiring structure IS1, photoelectric conversion layers PD, pixel isolation patterns 114, 115, and 116, first and second adhesive films 135 and 235, a second substrate 210, a second wiring structure IS2, a surface insulating film 140, color filters 170, grid patterns 150 and 160, microlenses 180, a contact film 350, a contact pattern 355, a connecting structure 450, a through via structure 550, and a pad pattern 555.

The first substrate 110 may be a semiconductor substrate. For example, the first substrate 110 may be a bulk silicon substrate or a silicon-on-insulator (SDI) substrate. The first substrate 110 may be a silicon substrate or may include a material other than silicon, such as, for example, silicon germanium, indium antimonide, a lead tellurium compound, indium arsenic, indium phosphide, gallium arsenide, or gallium antimonide. Alternatively, the first substrate 110 may be a base substrate having an epitaxial layer formed thereon.

The first substrate 110 may have first and second surfaces 110a and 110b, which are opposite to each other. The first surface 110a may also be referred to as a back side, and the second surface 110b may also be referred to as a front side. In example embodiments, the first surface 110a of the first substrate 110 may be a light-receiving surface. That is, the image sensor according to example embodiments of the present disclosure may be a back side-illuminated (BSI) image sensor.

A plurality of unit pixels may be disposed on the first substrate 110 in a sensor array region SAR. For example, the unit pixels may be arranged two-dimensionally (e.g., in a matrix) on a plane including first and second directions X and Y in the pixel array area PA.

The unit pixels may include the photoelectric conversion layers PD. The photoelectric conversion layers PD may be disposed in the first substrate 110 in the pixel array area PA. The photoelectric conversion layers PD may generate charges in proportion to the amount of light incident thereupon from the outside. In example embodiments, the photoelectric conversion layers PD may not be disposed in part of the light-blocking area OB. For example, the photoelectric conversion layers PD may be disposed in the first substrate 110 in part of the light-blocking area OB adjacent to the pixel array area PA, but not in part of the light-blocking area apart from the pixel array area PA.

The photoelectric conversion layers PD may include, for example, photodiodes, phototransistors, photogates, pinned photodiodes, organic photodiodes, quantum dots, and/or a combination thereof, but the present disclosure is not limited thereto.

The unit pixels may include first transistors TR1. In example embodiments, the first transistors TR1 may be disposed on the second surface 110b of the first substrate 110. The first transistors TR1 may be electrically connected to the photoelectric conversion layers PD to configure various transistors for processing electrical signals. For example, the first transistors TR1 may be transfer transistors, reset transistors, source follower transistors, or select transistors.

In example embodiments, the first transistors TR1 may be vertical transfer transistors. For example, parts of the first transistors TR1 may extend into the first substrate 110. As the first transistors TR1 can reduce the size of the unit pixels, the image sensor according to example embodiments of the present disclosure may be highly integrated.

The pixel isolation patterns 114, 115, and 116 may be disposed in the first substrate 110 in the sensor array region SAR. The pixel isolation patterns 114, 115, and 116 may not overlap vertically with the pad patterns 555 and the through via structure 550 of a pad region PR. For example, the pixel isolation patterns 114, 115, and 116 may be formed by patterning the first substrate 110 to form deep trenches 115t and burying the trenches 115t with an insulating material.

The pixel isolation patterns 114, 115, and 116 may define the unit pixels. The pixel isolation patterns 114, 115, and 116 may be arranged in a lattice shape in a plan view and may separate the unit pixels from one another.

The pixel isolation patterns 114, 115, and 116 may penetrate at least part of the first substrate 110. In example embodiments, the pixel isolation patterns 114, 115, and 116 may extend from the second surface 110b to the first surface 110a.

In example embodiments, the pixel isolation patterns may include a spacer film 116, a filling film 115, and a capping film 114. The spacer film 116 may extend along the sides of each of the trenches 115t. The filling film 115 may be disposed on the spacer film 116 to fill at least parts of the trenches 115t. The spacer film 116 may separate the filling film 115 from the first substrate 110. The capping film 114 may be disposed on the second surface 110b of the first substrate 110. The bottom surface of the capping film 114 may be on the same plane as the second surface 110b of the first substrate 110. The capping film 114 may be disposed on the filling film 115 to fill the rest of the trenches 115t.

The filling film 115 may include a conductive material. For example, the filling film 115 may include polysilicon (poly-Si), but the present disclosure is not limited thereto.

The spacer film 116 and the capping film 114 may include an insulating material. For example, the spacer film 116 and the capping film 114 may include at least one of silicon oxide, aluminum oxide, tantalum oxide, and a combination thereof, but the present disclosure is not limited thereto. The spacer film 116 may electrically insulate the filling film 115 from the first substrate 110. In some embodiments, the spacer film 116 may include an oxide having a lower refractive index than the first substrate 110. The spacer film 116, which has a lower refractive index than the first substrate 110, may refract or reflect light incident diagonally upon the photoelectric conversion layers PD. The spacer film 116 may prevent the random drift of photocharges generated in particular unit pixels by incident light to neighboring unit pixels.

The first wiring structure IS1 may be disposed on the first substrate 110. For example, the first wiring structure IS1 may cover the second surface 110b of the first substrate 110. The first substrate 110 and the first wiring structure IS1 may form a first substrate structure 100. The first substrate structure 100 may correspond to the first layer 30 of FIG. 2.

The first wiring structure IS1 may include one or more wirings. For example, the first wiring structure IS1 may include a first inter-wiring insulating film 120 and a plurality of wirings 122 and 124 in the first inter-wiring insulating film 120. The number of layers of wirings in the first wiring structure IS1 and the layout of the wirings in the first wiring structure IS1 are not particularly limited. The first inter-wiring insulating film 120 may include at least one of, for example, silicon oxide, silicon nitride, silicon oxynitride, and a low-k material having a lower dielectric constant than silicon oxide, but the present disclosure is limited thereto.

In example embodiments, the first wiring structure IS1 may include a first wiring 122 in the sensor array region SAR and a second wiring 124 in a connecting region CR. The first wiring 122 may be electrically connected to the unit pixels of the sensor array region SAR. For example, the first wiring 122 may be electrically connected to the first transistors TR1. The second wiring 124 may extend from the sensor array region SAR. For example, the first wiring 122 may include a plurality of first wirings, and the second wiring 124 may be electrically connected to at least some of the plurality of first wirings. As a result, the second wiring 124 may be electrically connected to the unit pixels of the sensor array region SAR.

The first and second wirings 122 and 124 may include at least one of, for example, tungsten (W), copper (Cu), aluminum (Al), gold (Au), silver (Ag), and an alloy thereof, but the present disclosure is not limited thereto.

The second substrate 210 may be a bulk silicon substrate or an SOI substrate. The second substrate 210 may be a silicon substrate or may include a material other than Si, such as, for example, silicon germanium, indium antimonide, a lead tellurium compound, indium arsenic, indium phosphide, gallium arsenide, or gallium antimonide. Alternatively, the second substrate 210 may be a base substrate having an epitaxial layer formed thereon.

The second substrate 210 may have third and fourth surfaces 210a and 210b, which are opposite to each other. In example embodiments, the third surface 210a of the second substrate 210 may face the second surface 110b of the first substrate 110.

A plurality of electronic elements may be disposed on the second substrate 210. For example, second transistors TR2 may be disposed on the third surface 210a of the second substrate 210. The second transistors TR2 may be electrically connected to the sensor array region SAR and may transmit electrical signals to, or receive electrical signals from, the unit pixels of the sensor array region SAR. For example, the second transistors TR2 may include transistors that form the control register block 11, the timing generator 12, the ramp signal generator 13, the row driver 14, the readout circuit 16, and the buffer 17 of FIG. 1.

The second wiring structure IS2 may be disposed on the second substrate 210. For example, the second wiring structure IS2 may cover the third surface 210a of the second substrate 210. The second substrate 210 and the second wiring structure IS2 may form a second substrate structure 200. The second substrate structure 200 may correspond to the second layer 40 of FIG. 2.

The second wiring structure IS2 may include one or more wirings. For example, the second wiring structure IS2 may include a second inter-wiring insulating film 220 and a plurality of wirings 222, 224, and 226 in the second inter-wiring insulating film 220. The number of layers of wirings in the second wiring structure IS2 and the layout of the wirings in the second wiring structure IS2 are not particularly limited. The second inter-wiring insulating film 220 may include at least one of, for example, silicon oxide, silicon nitride, silicon oxynitride, and a low-k material having a lower dielectric constant than silicon oxide, but the present disclosure is limited thereto. In example embodiments, the second wiring structure IS2 may include the same material as the first wiring structure IS1.

At least some of the wirings (e.g., wirings 222, 224, and 226) of the second wiring structure IS2 may be connected to the second transistors TR2. In example embodiments, the second wiring structure IS2 may include a third wiring 222 in the sensor array region SAR, a fourth wiring 224 in the connecting region CR, and a fifth wiring 226 in the pad region PR. In example embodiments, the fourth wiring 224 may be the uppermost wiring of the second wiring structure IS2 in the connecting region CR, and the fifth wiring 226 may be the uppermost wiring of the second wiring structure IS2 in the pad region PR. That is, the fourth and fifth wirings 224 and 226 may be closest to the second surface 110b of the first substrate 110. The third, fourth, and fifth wirings 222, 224, and 226 may include at least one of, for example, W, Cu, Al, Au, Ag, and an alloy thereof, but the present disclosure is not limited thereto.

In example embodiments, the first wiring structure IS1 may further include a first interlayer insulating film 130 and a first adhesive film 135. The first interlayer insulating film 130 may be disposed on the first inter-wiring insulating film 120. The first interlayer insulating film 130 may cover the bottom surface of the first inter-wiring insulating film 120. The first adhesive film 135 may be disposed on the first interlayer insulating film 130. The first adhesive film 135 may cover the bottom surface of the first interlayer insulating film 130. The second wiring structure IS2 may further include a second interlayer insulating film 230 and a second adhesive film 235. The second interlayer insulating film 230 may be disposed on the second inter-wiring insulating film 220. The second interlayer insulating film 230 may cover the top surface of the second inter-wiring insulating film 220. The second adhesive film 235 may be disposed on the second interlayer insulating film 230. The second adhesive film 235 may cover the top surface of the second interlayer insulating film 230. The second adhesive film 235 may be bonded to the first adhesive film 135. Accordingly, the second wiring structure IS2 may be attached to the first wiring structure IS1. For example, the top surface of the second adhesive film 235 may be bonded to the bottom surface of the first adhesive film 135.

The first and second interlayer insulating films 130 and 230 may include at least one of, for example, silicon oxide, silicon nitride, silicon oxynitride, and a low-k material having a lower dielectric constant than silicon oxide, but the present disclosure is not limited thereto. The first and second adhesive films 135 and 235 may include, for example, silicon carbonitride (SiCN), but the present disclosure is not limited thereto.

The surface insulating film 140 may be disposed on the first surface 110a of the first substrate 110. The surface insulating film 140 may extend along the first surface 110a of the first substrate 110.

The surface insulating film 140 may include an insulating material. For example, the surface insulating film 140 may include at least one of silicon oxide, silicon nitride, silicon oxynitride, aluminum oxide, hafnium oxide, and a combination thereof, but the present disclosure is not limited thereto. The surface insulating film 140 may be a multilayer film. For example, the surface insulating film 140 may include an aluminum oxide film, a hafnium oxide film, a silicon oxide film, a silicon nitride film, and a hafnium oxide film that are sequentially stacked on the first surface 110a of the first substrate 110, but the present disclosure is not limited thereto.

The surface insulating film 140 may function as an antireflection film and may improve the light reception of the photoelectric conversion layers PD by preventing the reflection of light incident upon the first substrate 110. Also, the surface insulating film 140 may function as a planarization layer so that the color filters 170 and the microlenses 180 may be formed at a uniform height.

The color filters 170 may be disposed on the surface insulating film 140. The color filters 170 may be arranged to correspond to the unit pixels of the sensor array region SAR.

The color filters 170 may include various colors filters for various unit pixels. For example, the color filters 170 may be arranged in a Bayer pattern layout including red filters, green filters, and blue filters, but the present disclosure is not limited thereto. In another example, the color filters 170 may include yellow filters, magenta filters, and cyan filters and may further include white filters.

In some embodiments, grid patterns 150 and 160 may be disposed between the color filters 170. The grid patterns 150 and 160 may be disposed on the surface insulating film 140. The grid patterns 150 and 160 may be interposed between the color filters 170. In some embodiments, the grid patterns 150 and 160 may be disposed to overlap with the pixel isolation patterns 114, 115, and 116 in a vertical direction (e.g., the third direction Z).

In some embodiments, the grid patterns may include conductive patterns 150 and low-refractive index patterns 160. The conductive patterns 150 and the low-refractive index patterns 160 may be sequentially stacked on, for example, the surface insulating film 140.

The conductive patterns 150 may include at least one of, for example, titanium (Ti), titanium nitride (TiN), tantalum (Ta), tantalum nitride (TaN), W, Al, and Cu, but the present disclosure is not limited thereto. The conductive patterns 150 may prevent electric charges generated by, for example, electrostatic discharge (ESD), from accumulating on the surface (e.g., on the first surface 110a) of the first substrate 110 and may effectively prevent any ESD bruise defects.

The low-refractive index patterns 160 may include a low-refractive index material having a lower refractive index than silicon (Si). For example, the low-refractive index patterns 160 may include at least one of silicon oxide, aluminum oxide, tantalum oxide, and a combination thereof, but the present disclosure is not limited thereto. The low-refractive index patterns 160 may improve the quality of the image sensor according to example embodiments of the present disclosure by refracting or reflecting light incident diagonally thereupon to improve the efficiency of collection of light.

In example embodiments, a first passivation film 165 may be disposed on the surface insulating film 140 and the grid patterns 150 and 160. For example, the first passivation film 165 may extend conformally along the profiles of the top surface of the surface insulating film 140 and the sides and the top surface of each of the grid patterns 150 and 160.

The first passivation film 165 may include, for example, aluminum oxide, but the present disclosure is not limited thereto. The first passivation film 165 may prevent the surface insulating film 140 and the grid patterns 150 and 160 from being damaged.

The microlenses 180 may be disposed on the color filters 170. The microlenses 180 may be arranged to correspond to the unit pixels in the sensor array region SAR.

The microlenses 180 may have a convex shape and a predetermined curvature radius. Accordingly, the microlenses 180 may collect light incident upon the photoelectric conversion layers PD. The microlenses 180 may include, for example, a light-transmitting resin, but the present disclosure is not limited thereto.

In example embodiments, a second passivation film 185 may be disposed on the microlenses 180. The second passivation film 185 may extend along the surfaces of the microlenses 180. The second passivation film 185 may include, for example, an inorganic material oxide film (e.g., a film of silicon oxide, titanium oxide, zirconium oxide, hafnium oxide, or a combination thereof), but the present disclosure is not limited thereto. In example embodiments, the second passivation film 185 may include a low-temperature oxide (LTO).

The second passivation film 185 may protect the microlenses 180 from the outside. For example, as the second passivation film 185 includes an inorganic oxide film, the second passivation film 185 can protect the microlenses 180, which include an organic material. The second passivation film 185 may improve the quality of the image sensor according to example embodiments of the present disclosure by improving the light collection efficiency of the microlenses 180. For example, the second passivation film 185 can fill the spaces between the microlenses 180 and can thus reduce the reflection, refraction, or scattering of incident light arriving at the spaces between the microlenses 180.

In example embodiments, the contact film 350 may be disposed in the light-blocking area OB. The contact film 350 may be disposed on the surface insulating film 140, in the light-blocking area OB. The contact film 350 may be in contact with the pixel isolation patterns 114, 115, and 116.

For example, contact trenches 355t, which expose the pixel isolation patterns 114, 115, and 116, may be formed in the second substrate 210 and the surface insulating film 140 in the light-blocking area OB. The contact film 350 may be disposed in the contact trenches 355t to contact the pixel isolation patterns 114, 115, and 116, in the light-blocking area OB. In example embodiments, the contact film 350 may extend along the contact trenches 355t. The contact film 350 may extend along the profiles of the sides and the bottom surface of each of the contact trenches 355t.

The contact film 350 may include at least one of, for example, Ti, TiN, Ta, TaN, W, Al, and Cu, but the present disclosure is not limited thereto.

The contact pattern 355 may be disposed on the contact film 350 to fill the contact trenches 355t. The contact pattern 355 may include at least one of, for example, W, Cu, Al, Au, Ag, and an alloy thereof, but the present disclosure is not limited thereto. In example embodiments, the contact pattern 355 may include a different material from the contact film 350. For example, the contact film 350 may include W, and the contact pattern 355 may include Al.

The contact film 350 may apply a ground or minus voltage to the filling film 115. In this case, the image sensor according to example embodiments of the present disclosure can effectively prevent ESD bruise defects. The term “ESD bruise defect” may refer to a smudge such as a bruise that appears in an image due to the accumulation of electric charges, caused by ESD, in the first substrate 110.

The first passivation film 165 may cover the contact film 350 and the contact pattern 355. For example, the first passivation film 165 may extend along the profiles of the contact film 350 and the contact pattern 355.

The connecting structure 450 may be disposed in the connecting region CR. The connecting structure 450 may penetrate the first substrate structure 100 and the first and second interlayer insulating films 140 and 240. The connecting structure 450 may be disposed on the surface insulating film 140, in the connecting region CR. The connecting structure 450 may electrically connect the first and second substrate structures 100 and 200.

For example, a connecting trench 455t may penetrate the first substrate 110 and the first substrate structure 100, in the connecting region CR. The connecting trench 455t may expose at least a portion of the second wiring 124 and at least a portion of the fourth wiring 224. The connecting trench 455t may expose the top surface of at least a portion of the second wiring 124 and/or sides of at least a portion of the second wiring 124 and may also expose the top surface of at least a portion of the fourth wiring 224. The bottom surface of the connecting trench 455t may be stepped.

The connecting structure 450 may be disposed in the connecting trench 455t to connect the second and fourth wirings 124 and 224. That is, the connecting structure 450 may extend from the first surface 110a of the first substrate 110 to electrically connect the second and fourth wirings 124 and 224. In example embodiments, the connecting structure 450 may extend along the connecting trench 455t. The connecting structure 450 may extend along the profiles of the sides and the bottom surface of the connecting trench 455t.

The connecting structure 450 may include at least one of, for example, Ti, TiN, Ta, TaN, W, Al, Cu, and a combination thereof, but the present disclosure is not limited thereto.

In example embodiments, the first passivation film 165 may cover the connecting structure 450. For example, the first passivation film 165 may extend along the profile of the connecting structure 450.

In example embodiments, a filling insulating film 460 may be disposed on the connecting structure 450 to fill at least part of the connecting trench 455t. In example embodiments, the filling insulating film 460 may have a convex top surface due to the properties of processes for forming the filling insulating film 460, such as a deposition process and/or a planarization process, but the present disclosure is not limited thereto. The filling insulating film 460 may include, for example, a Si-based insulating material (e.g., silicon nitride, silicon oxide, or silicon oxynitride) or a high-k material (e.g., hafnium oxide or aluminum oxide), but the present disclosure is not limited thereto.

In example embodiments, a capping pattern 465 may be disposed on the connecting structure 450 and the filling insulating film 460. For example, part of the capping pattern 465 may protrude from the top surface of the connecting structure 450. In example embodiments, the capping pattern 465 may not be provided.

The through via structure 550 may be disposed in the pad region PR. The through via structure 550 may be disposed on the surface insulating film 140, in the pad region PR. The through via structure 550 may penetrate the first substrate 110 and the first wiring structure IS1 to be electrically connected to the second wiring structure IS2. The through via structure 550 may electrically connect the second substrate structure 200 and an external device.

For example, a via trench 555t may be formed in the first and second substrate structures 100 and 200, in the pad region PR, to expose the fifth wiring 226. The via trench 555t may include first and second via trenches 551t and 552t.

The first via trench 551t may penetrate part of the first substrate 110 and parts of the first and second wiring structures IS1 and IS2. The first via trench 551t may expose at least a portion of the fifth wiring 226. For example, the first via trench 551t may have a first width W1.

The second via trench 552t may be disposed on the first via trench 551t. The second via trench 552t may be disposed in the first substrate 110. The second via trench 552t may penetrate part of the first substrate 110. The second via trench 552t may have a second width W2. The second width W2 may be greater than the first width W1. At least part of the first via trench 551t may overlap with the second via trench 552t in the vertical direction (e.g., in a direction from the second surface 110b to the first surface 110a of the first substrate 110). For example, the first via trench 551t may be disposed at the center of the second via trench 552t, but the present disclosure is not limited thereto.

The through via structure 550 may be disposed in the via trench 555t. The through via structure 550 may extend along the via trench 555t. The through via structure 550 may extend along the profiles of the sides and the bottom surface of the via trench 555t. The through via structure 550 may extend conformally along, for example, the via trench 555t. The through via structure 550 may be in contact with the fifth wiring 226. The through via structure 550 may be electrically connected to the fifth wiring 226.

That is, the through via structure 550 may have an integral structure extending from the top surface of the surface insulating film 140 to the fifth wiring 226. The integral structure may refer to a structure that is formed by the same manufacturing process.

The pad pattern 555 may be disposed on the through via structure 550 and may fill at least part of the via trench 555t. The pad pattern 555 may extend from the first surface 110a of the first substrate 110 to the second interlayer insulating film 230. The pad pattern 555 may include a first portion 551, which may fill the first via trench 551t, and a second portion 552, which may fill the second via trench 552t. Accordingly, the second portion 552 of the pad pattern 555 may have a larger width than the first portion 551 of the pad pattern 555. The first portion 551 may be disposed in the first wiring structure IS1 and the first substrate 110, and the second portion 552 may be disposed on the first portion 551, in the first substrate 110. The pad pattern 555 may have an integral structure filling the via trench 555t.

The through via structure 550 may extend along at least part of the pad pattern 555 to be electrically connected to the fifth wiring 226. The through via structure 550 may extend along the sides and the bottom surface of the pad pattern 555.

The pad pattern 555 may include at least one of, for example, W, Cu, Al, Au, Ag, and an alloy thereof, but the present disclosure is not limited thereto.

In a case where the through via structure 550 is formed to extend along a first trench, which is formed in the first substrate 110 and a second trench, which is spaced apart from the first trench and extends to the fifth wiring 226, and where the pad pattern 555 is formed to fill the first trench, voltages applied from the pad pattern 555 may be transmitted to the second substrate structure 200 through the through via structure 550.

The pad pattern 555 and the through via structure 550 may be disposed in one via trench 555t. Accordingly, the areas occupied by the pad pattern 555 and the through via structure 550 may be reduced, and the size of the image sensor according to some embodiments of the present disclosure may be reduced. Also, the path along which voltages from the pad pattern 555 are transmitted to the second substrate structure 200 may be reduced.

Also, as the through via structure 550 does not extend along the surface insulating film 140 between the first and second trenches, the exposure of the through via structure 550 may be reduced. As the exposure of the through via structure 550 to external temperature or moisture may be reduced, the oxidation of the through via structure 550 may be prevented or alleviated. Accordingly, the quality of the image sensor according to example embodiments of the present disclosure may be improved.

In example embodiments, the first passivation film 165 may cover the through via structure 550. For example, the first passivation film 165 may extend along the profile of the through via structure 550. In example embodiments, the first passivation film 165 may expose the pad pattern 555.

In example embodiments, insulating patterns 118 may be disposed in the first substrate 110. For example, isolation trenches 118t may be formed in the first substrate 110. The isolation trenches 118t may be disposed on at least one side of the via trench 555t. The isolation trenches 118t may be spaced apart from the via trench 555t. The isolation trenches 118t may extend from the first surface 110a of the first substrate 110. For example, the isolation trenches 118t may extend from the first surface 110a to the second surface 110b. The insulating patterns 118 may fill the isolation trenches 118t. In example embodiments, the insulating patterns 118 may be formed near the contact film 350, in the light-blocking area OB.

The insulating patterns 118 may include at least one of, for example, silicon oxide, silicon nitride, silicon oxynitride, aluminum oxide, hafnium oxide, and a combination thereof, but the present disclosure is not limited thereto.

In example embodiments, a light-blocking filter 170C may be disposed on the contact film 350 and the connecting structure 450. For example, the light-blocking filter 170C may partially cover the first passivation film 165, in the light-blocking area OB and the connecting region CR. The light-blocking filter 170C may block light incident upon the first substrate 110. The light-blocking filter 170C may include, for example, a blue color filter.

In example embodiments, a third passivation film 380 may be disposed on the light-blocking filter 170C. For example, the third passivation film 380 may partially cover the first passivation film 165, in the light-blocking area OB, the connecting region CR, and the pad region PR. In example embodiments, the second passivation film 185 may extend along the surface of the third passivation film 380. For example, the third passivation film 380 may extend along the surface of the light-blocking filter 170C. The third passivation film 380 may include, for example, a light-transmitting resin, but the present disclosure is not limited thereto. In example embodiments, the third passivation film 380 may include the same material as the microlenses 180.

In example embodiments, the second and third passivation films 185 and 380 may expose the pad pattern 555. For example, an exposure opening ER, which exposes the pad pattern 555, may be formed in the second and third passivation films 185 and 380.

In example embodiments, the pad pattern 555, which is connected to an external device, may apply a ground or minus voltage to the contact film 350. For example, the ground or minus voltage from the pad pattern 555 may be applied to the contact film 350 through the through via structure 550, the fifth wiring 226, the fourth wiring 224, and the connecting structure 450. Electrical signals generated by the photoelectric conversion layers PD may be transmitted to the outside through the first wiring 122, the second wiring 124, the connecting structure 450, the fourth wiring 224, the fifth wiring 226, the through via structure 550, and the pad pattern 555. The pad pattern 555 may be an input/output pad.

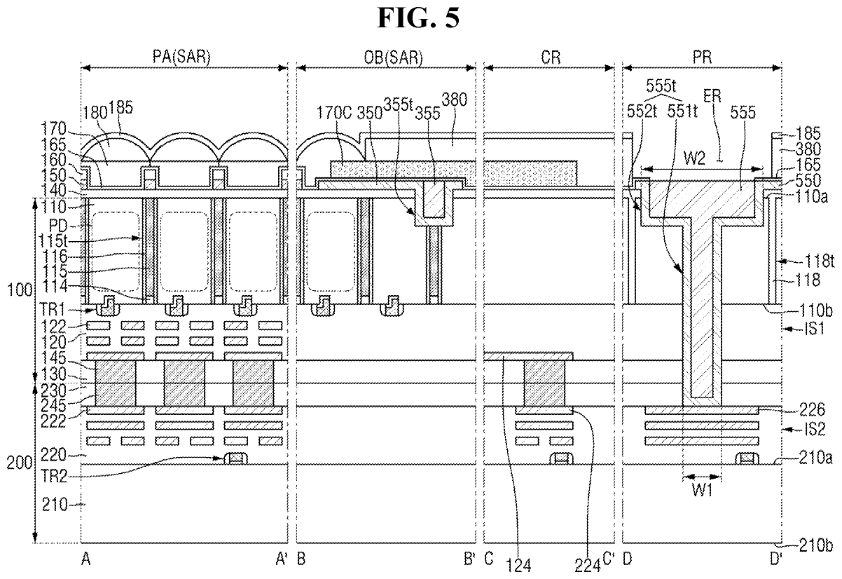

Referring to FIGS. 3 and 5, at least parts of first and second substrate structures 100 and 200 may be connected in a chip-to-chip (C2C) manner.

The C2C manner may refer to fabricating an upper chip on the first wafer (e.g., a first substrate 110), fabricating a lower chip on a second wafer (e.g., a second substrate 210), and bonding the upper and lower chips.

For example, first bonding patterns 145, which are exposed from the bottom surface of a first interlayer insulating film 130, may be formed in the first interlayer insulating film 130, and second bonding patterns 245, which correspond to the first bonding patterns 145 and are exposed from the top surface of a second interlayer insulating film 230, may be formed in the second interlayer insulating film 230. The first bonding patterns 145 may be electrically connected to the second bonding patterns 245 when bonding the first and second interlayer insulating films 130 and 230. As a result, the first and second substrate structures 100 and 200 may be electrically connected.

For example, the first bonding patterns 145 and the second bonding patterns 245 may include Cu and may be connected in a Cu-Cu bonding manner, but the present disclosure is not limited thereto. Alternatively, the first bonding patterns 145 and the second bonding patterns 245 may include Al or W.

The first bonding patterns 145 and the second bonding patterns 245 are illustrated as being formed in a pixel array area PA and a connecting region CR, but the present disclosure is not limited thereto. For example, the first bonding patterns 145 and the second bonding patterns 245 may be formed in at least one of the pixel array area PA, a light-blocking area OB, the connecting region CR, and a pad region PR.

A first via trench 551t may penetrate parts of the first substrate 110, a first wiring structure IS1, and a second wiring structure IS2. The first via trench 551t may expose the top surface of at least a portion of a fifth wiring 226. A through via structure 550 may be in contact with the fifth wiring 226. The through via structure 550 may extend along the via trench 555t to be electrically connected to the fifth wiring 226.

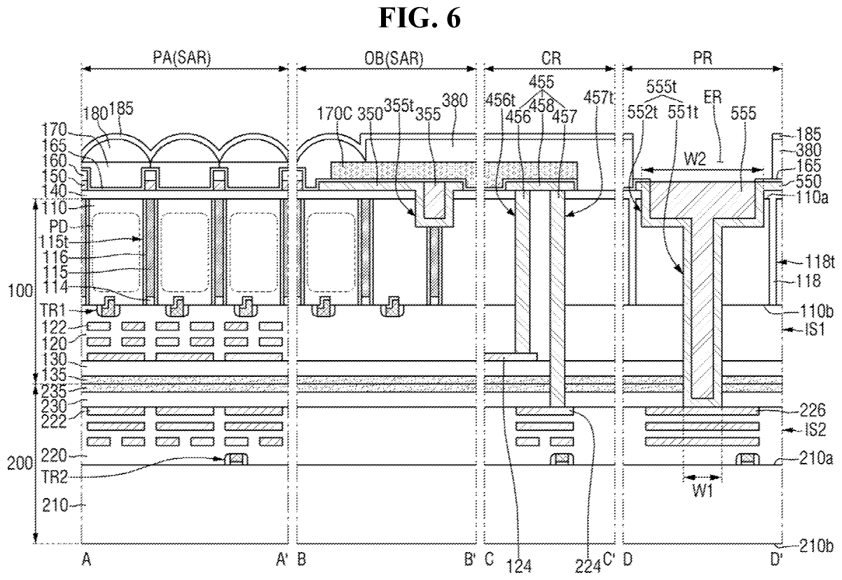

Referring to FIGS. 3 and 6, a connecting structure 455 may include a first portion 456, a second portion 457, and a third portion 458.

A first connecting trench 456t may penetrate at least part of a first substrate structure 100, in a connecting region CR. The first connecting trench 456t may expose at least a portion of a second wiring 124. For example, the first connecting trench 456t may expose the top surface of at least a portion of the second wiring 124. The first portion 456 may be disposed in the first connecting trench 456t.

A second connecting trench 457t may be spaced apart from the first connecting trench 456t. The second connecting trench 457t may penetrate the first substrate structure 100 and first and second insulating films 140 and 240, in the connecting region CR. The second connecting trench 457t may expose at least a portion of a fourth wiring 224. For example, the second connecting trench 457t may expose the top surface of at least some of the fourth wiring 224. The second portion 457 may be disposed in the second connecting trench 457t.

The third portion 458 may be disposed on a surface insulating film 140. The third portion 458 may extend along the surface insulating film 140 and may be connected to the first and second portions 456 and 457.

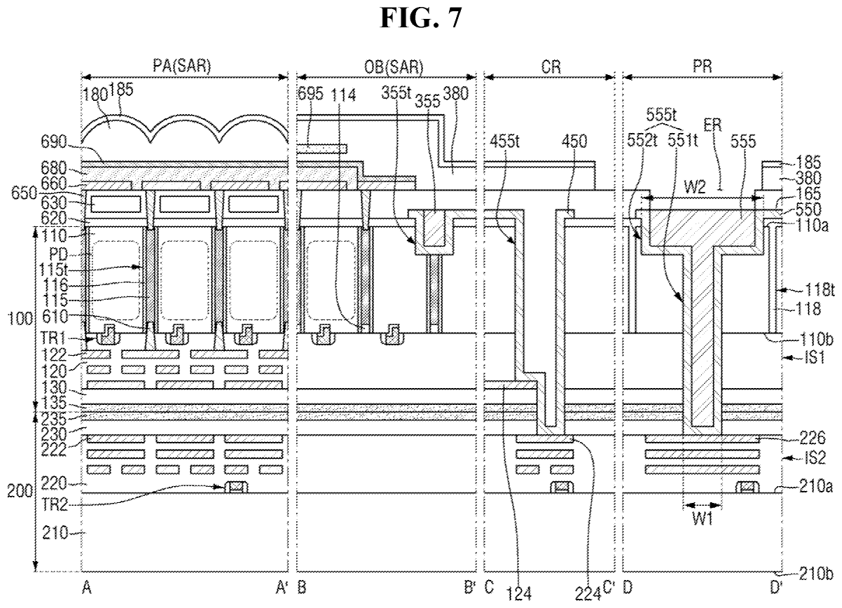

Referring to FIGS. 3 and 7, an image sensor according to example embodiments of the present disclosure may include first contact plugs 610, a surface insulating film 620, color filters 630, a third interlayer insulating film 640, second contact plugs 650, lower electrodes 660, an organic photoelectric conversion layer 680, an upper electrode 690, and an optical black pattern 695.

The first contact plugs 610 may be disposed in a pixel array area PA. The first contact plugs 610 may penetrate part of a first inter-wiring insulating film 120 and a capping film 114 in the pixel array area PA. The first contact plugs 610 may connect a filling film 115 and the uppermost wiring of a first wiring structure IS1 (i.e., a first wiring 122). That is, the first wiring 122 may be the closest wiring to a second surface 110b of a first substrate 110. In example embodiments, parts of the first contact plugs 610 may be disposed in the filling film 115. For example, the first contact plugs 610 may be single films. In another example, each of the first contact plugs 610 may include a barrier film, which extends along the sides and the bottom surface of each of trenches where the first contact plugs 610 are formed, and a conductive film, which is formed on the barrier film to fill the trenches.

The surface insulating film 620 may be disposed on a first surface 110a of the first substrate 110. The surface insulating film 620 may extend along the first surface 110a of the first substrate 110. The surface insulating film 620 may include an insulating material. For example, the surface insulating film 620 may include at least one of, for example, silicon oxide, silicon nitride, silicon oxynitride, aluminum oxide, hafnium oxide, and a combination thereof, but the present disclosure is not limited thereto. The surface insulating film 620 may be a multifilm. For example, the surface insulating film 620 may include an aluminum oxide film, a hafnium oxide film, a silicon oxide film, a silicon nitride film, and a hafnium oxide film that are sequentially stacked on the first surface 110a of the first substrate 110, but the present disclosure is not limited thereto.

The third interlayer insulating film 640 may be disposed on the surface insulating film 620. The third interlayer insulating film 640 may fill a connecting trench 455t, on a connecting structure 450. The third interlayer insulating film 640 may include at least one of, for example, silicon oxide (SiO₂), silicon nitride (SiN), silicon oxynitride (SiON), a low-k material, and a combination thereof.

The second contact plugs 650 may penetrate the third interlayer insulating film 640 and the surface insulating film 620. The second contact plugs 650 may connect the filling film 115 and the lower electrodes 660. In example embodiments, parts of the second contact plugs 650 may be disposed in the filling film 115. For example, the second contact plugs 650 may be single films. In another example, the second contact plugs 650 may include a barrier film, which extends along the sides and the bottom surface of each of trenches where the second contact plugs 650 are formed, and a conductive film, which is formed on the barrier film to fill the trenches.

The color filters 630 may be disposed in the pixel array area PA. The color filters 630 may be disposed in the third interlayer insulating film 640. The color filters 630 may be disposed on at least one side of each of the second contact plugs 650. In example embodiments, the top surfaces of the color filters 630 may be formed to be lower than the top surface of the third interlayer insulating film 640. The color filters 630 may include red color filters or green color filters.

The lower electrodes 660 may be disposed on the third interlayer insulating film 640. The lower electrodes 660 may be electrically connected to the second contact plugs 650. The lower electrodes 660 may be transparent electrodes. The lower electrodes 660 may include at least one of, for example, indium tin oxide (ITO), zinc oxide (ZnO), tin dioxide (SnO₂), antimony-doped tin oxide (ATO), aluminum-doped zinc oxide (AZO), gallium-doped zinc oxide (GZO), titanium dioxide (TiO₂), fluorine-doped tin oxide (FTO), and a combination thereof.

The organic photoelectric conversion layers 680 may be disposed to cover the lower electrodes 660. The organic photoelectric conversion layers 680 may generate photocharges in proportion to the amount of light incident thereupon from the outside. That is, the organic photoelectric conversion layers 680 may receive light and may convert optical signals into electrical signals. The photoelectric conversion layers 680 may perform photoelectric conversion on, for example, green light.

The upper electrode 690 may be disposed on the organic photoelectric conversion layers 680. The upper electrode 690 may be a transparent electrode. The upper electrode 690 may include at least one of, ITO, ZnO, SnO₂, ATO, AZO, GZO, TiO₂, FTO, and a combination thereof.

A microlens 180 may be disposed on the upper electrode 690. The optical black pattern 695 may be disposed in the microlens 180, in the light-blocking area OB. The optical black pattern 695 may include, for example, an opaque metal. The optical black pattern 695 may include, for example, Al.

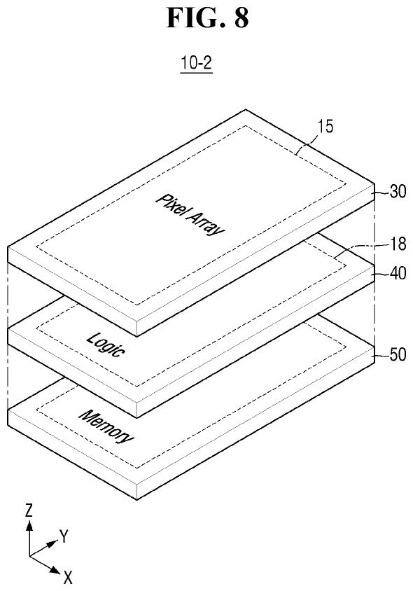

FIG. 8 is a diagram of an image sensor according to example embodiments of the present disclosure.

Referring to FIG. 8, an image sensor 10-2 may include a first layer 30, a second layer 40, and a third layer 50. The third layer 50, the second layer 40, and the first layer 30 may be sequentially stacked in a third direction Z.

The third layer 50 may include a memory device. For example, the third layer may include a nonvolatile memory device such as a dynamic random-access memory (DRAM) or a static random-access memory (SRAM). The third layer 50 may receive signals from the first or second layer 30 or 40 and may process the received signals via the memory device. That is, the image sensor 10-2 may be a 3-stack image sensor including three layers (i.e., the first, second, and third layers 30, 40, and 50).

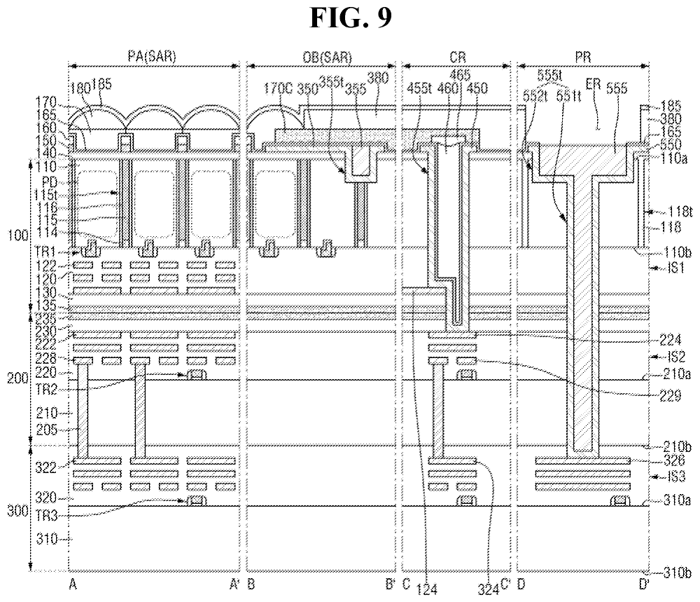

FIGS. 9, 10 and 11 are cross-sectional views of image sensors according to example embodiments of the present disclosure. Specifically, FIGS. 9, 10, and 11 are cross-sectional views taken along lines A-A′, B-B′, C-C′ and D-D′ as shown in FIG. 3, although implemented with the third layer 50 of FIG. 8. For convenience, descriptions of features or elements that have already been described above with reference to FIGS. 1 through 8 will be omitted or simplified.

Referring to FIGS. 3, 8 and 9 through 11, each of the image sensors according to example embodiments of the present disclosure may further include a third substrate structure 300.

The third substrate 310 may have fifth and sixth surfaces 310a and 310b, which are opposite to each other. In example embodiments, the fifth surface 310a of the third substrate 310 may face a fourth surface 210b of a second substrate 210. A plurality of electronic elements may be disposed on the third substrate 310. For example, third transistors TR3 may be disposed on the fifth surface 310a of the third substrate 310.

A third wiring structure IS3 may be disposed on the third substrate 310. For example, the third wiring structure IS3 may cover the fifth surface 310a of the third substrate 310. The third substrate 310 and the third wiring structure IS3 may form the third substrate structure 300. The third substrate structure 300 may correspond to the third layer 50 of FIG. 8.

The third wiring structure IS3 may include one or more wirings. For example, the third wiring structure IS3 may include a third inter-wiring insulating film 320 and a plurality of wirings 322, 324, and 326 in the third inter-wiring insulating film 320. The number of layers of wirings in the third wiring structure IS3 and the layout of the wirings in the third wiring structure IS3 are not particularly limited. The third inter-wiring insulating film 320 may include at least one of, for example, silicon oxide, silicon nitride, silicon oxynitride, and a low-k material having a lower dielectric constant than silicon oxide, but the present disclosure is limited thereto.

At least some of the wirings (e.g., wirings 322, 324, and 326) of the third wiring structure IS3 may be connected to the third transistors TR3. In example embodiments, the third wiring structure IS3 may include a sixth wiring 322 in a sensor array region SAR, a seventh wiring 324 in a connecting region CR, and an eighth wiring 326 in a pad region PR. In example embodiments, the sixth wiring 322 may be the uppermost wiring of the third wiring structure IS3 in a pixel array area PA, the seventh wiring 324 may be the uppermost wiring of the third wiring structure IS3 in the connecting region CR, and the eighth wiring 326 may be the uppermost wiring of the third wiring structure IS3 in the pad region PR. That is, the sixth, seventh, and eighth wirings 322, 324, and 326 may be closest to the fourth surface 210b of the second substrate 210. The sixth, seventh, and eighth wirings 322, 324, and 326 may include at least one of, for example, W, Cu, Al, Au, Ag, and an alloy thereof, but the present disclosure is not limited thereto.

A second wiring structure IS2 may further include a ninth wiring 228 in the pixel array area PA and a tenth wiring 229 in the connecting region CR. In example embodiments, the ninth wiring 228 may be the lowermost wiring of the second wiring structure IS2 in the pixel array area PA, and the tenth wiring 229 may be the lowermost wiring of the second wiring structure IS2 in the connecting region CR. That is, the ninth and tenth wirings 228 and 220 may be closest to a third surface 210a of the second substrate 210.

Through electrodes 205 may penetrate the second wiring structure IS2, the second substrate 210, and the third wiring structure IS3. The through electrodes 205 may connect, for example, the sixth and ninth wirings 322 and 229 and the seventh and tenth wirings 324 and 229. As a result, a second substrate structure 200 and the third substrate structure 300 may be electrically connected.

The through electrodes 205 are illustrated as being formed in the pixel array area PA and the connecting region CR, but the present disclosure is not limited thereto. For example, the through electrodes 205 may be formed in at least one of the pixel array area PA, a light-blocking area OB, the connecting region CR, and the pad region PR.

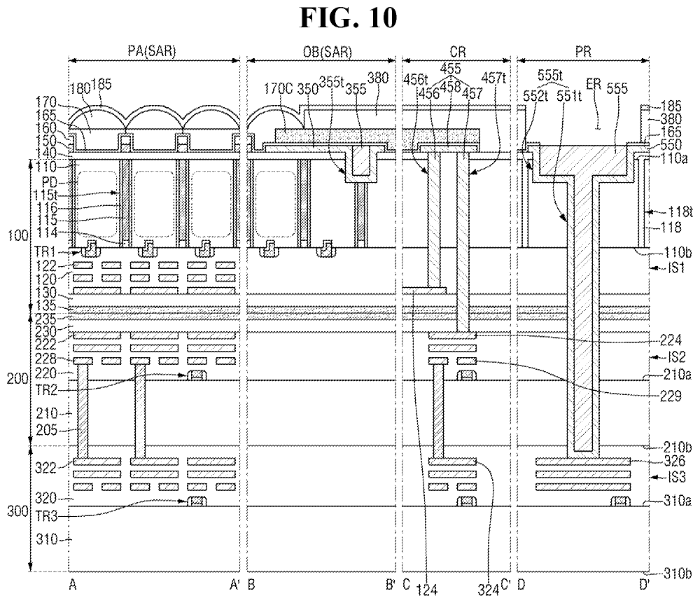

Referring to FIGS. 9 and 10, a through via structure 550 may penetrate parts of a first substrate 110, a first wiring structure IS1, the second wiring structure IS2, the second substrate 210, and the third wiring structure IS3 to be electrically connected to the third wiring structure IS3.

For example, a first via trench 551t may penetrate parts of the first substrate 110, the first wiring structure IS1, the second wiring structure IS2, the second substrate 210, and the third wiring structure IS3. The first via trench 551t may expose at least a portion of the eighth wiring 326. For example, the first via trench 551t may expose the top surface of at least a portion of the eighth wiring 326. The through via structure 550 may extend along a via trench 555t. The through via structure 550 may be in contact with the eighth wiring 326. As a result, the through via structure 550 may be electrically connected to the eighth wiring 326.

Accordingly, a first substrate structure 100 and the second substrate structure 200 may be electrically connected by a connecting structure 455, and the second and third substrate structures 200 and 300 may be electrically connected by the through electrodes 205. The connecting structure 455 of FIG. 9 may be substantially the same as the connecting structure 450 of FIG. 4, and the connecting structure 455 of FIG. 10 may be substantially the same as the connecting structure 455 of FIG. 6.

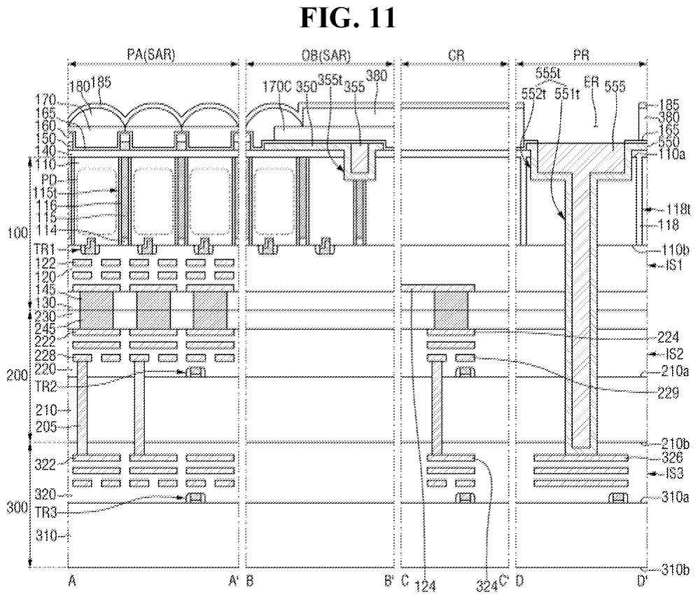

Referring to FIG. 11, a through via structure 550 may penetrate parts of the first substrate 110, the first wiring structure IS1, first and second interlayer insulating films 130 and 230, the second wiring structure IS2, the second substrate 210, and the third wiring structure IS3 to be electrically connected to the third wiring structure IS3.

For example, a first via trench 551t may penetrate parts of the first substrate 110, the first wiring structure IS1, the first and second interlayer insulating films 130 and 230, the second wiring structure IS2, the second substrate 210, and the third wiring structure IS3. The first via trench 551t may expose at least a portion of the eighth wiring 326. For example, the first via trench 551t may expose the top surface of at least a portion of the eighth wiring 326. The through via structure 550 may extend along a via trench 555t. The through via structure 550 may be in contact with the eighth wiring 326. As a result, the through via structure 550 may be electrically connected to the eighth wiring 326.

A first substrate structure 100 and a second substrate structure 200 may be electrically connected by first bonding patterns 145 and second bonding patterns 245, and the second substrate structure 200 and a third substrate structure 300 may be electrically connected by through electrodes 205. The first bonding patterns 145 and the second bonding patterns 245 of FIG. 11 may be substantially the same as the first bonding patterns 145 and the second bonding patterns 245, respectively, of FIG. 5.

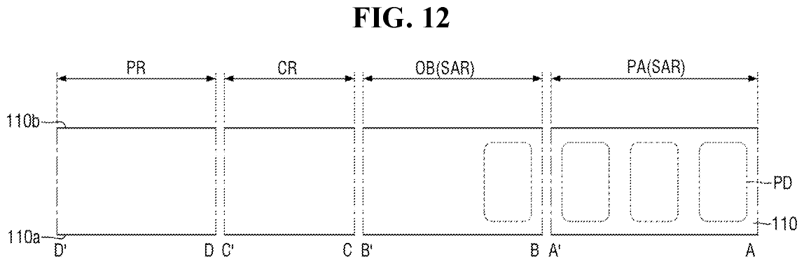

FIGS. 12, 13, 14, 15, 16, 17, 18 and 19 are cross-sectional views illustrating a method of fabricating an image sensor according to example embodiments of the present disclosure. For convenience, descriptions of features or elements that have already been described above with reference to FIGS. 1 through 11 will be omitted or simplified.

Referring to FIG. 12, a first substrate 110 may be provided.

The first substrate 110 may be a semiconductor substrate. The first substrate 110 may have first and second surfaces 110a and 110b, which are opposite to each other. A plurality of unit pixels may be formed in the first substrate 110, in a sensor array region SAR. A photoelectric conversion layer PD may be formed in each of the unit pixels.

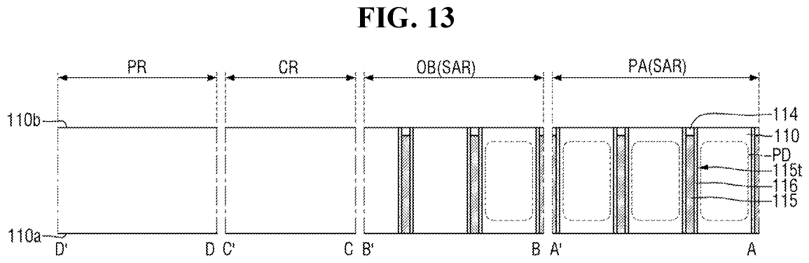

Referring to FIG. 13, pixel isolation patterns 114, 115, and 116 may be formed in the first substrate 110.

The pixel isolation patterns 114, 115, and 116 may be formed in the first substrate 110, in the sensor array region SAR. For example, deep trenches 115t may be formed in the first substrate 110 by performing etching on the second surface 110b of the first substrate 110. Thereafter, a spacer film 116, which extends along the sidewalls of each of the trenches 115t, may be formed. The spacer film 116 may extend from the second surface 110b to the first surface 110a of the first substrate 110. A filling film 115, which may fill parts of the trenches 115t, may be formed on the spacer film 116. A capping film 114, which may fill the trenches 115t, may be formed on the filling film 115.

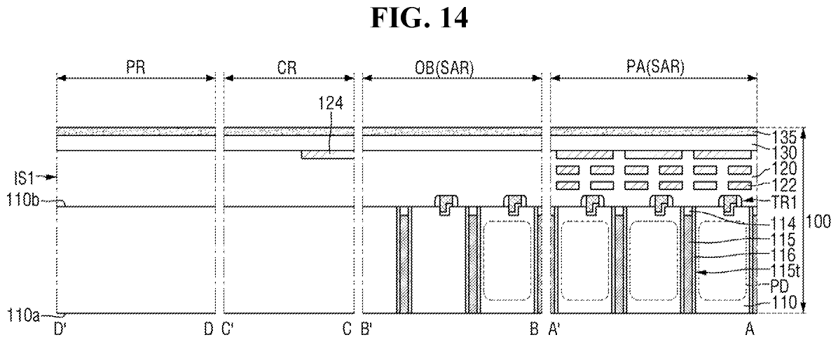

Referring to FIG. 14, first transistors TR1 and a first wiring structure IS1 may be formed on the second surface 110b of the first substrate 110.

The first transistors TR1 may be various transistors connected to photoelectric conversion layers PD to process electrical signals. The first wiring structure IS1 may include a first inter-wiring insulating film 120 and a plurality of wirings 122 and 124 in the first inter-wiring insulating film 120. A first interlayer insulating film 130 and a first adhesive film 135 may be formed on the first inter-wiring insulating film 120. In this manner, a first substrate structure 100, which includes the first substrate 110 and the first wiring structure IS1, may be formed.

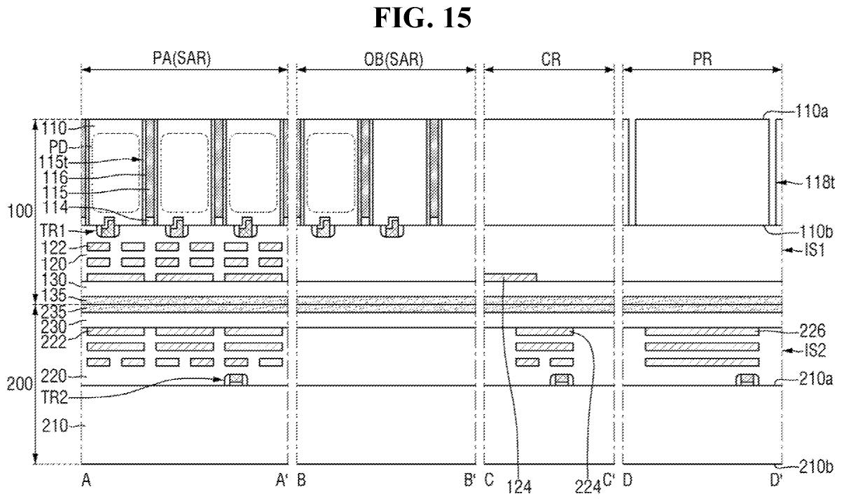

Referring to FIG. 15, the first substrate structure 100 may be attached on a second substrate structure 200.

The second substrate structure 200 may include a second substrate 210 and a second wiring structure IS2. Second transistors TR2 may be formed on a third surface 210a of the second substrate 210. The second wiring structure IS2 may include a second inter-wiring insulating film 220 and a plurality of wirings 222, 224, and 226 in the second inter-wiring insulating film 220. The second wiring structure IS2 may include a second interlayer insulating film 230 and a second adhesive film 235, which are formed on the second inter-wiring insulating film 220.

The first and second substrate structures 100 and 200 may be attached together such that the second surface 110b of the first substrate 110 and the third surface 210a of the second substrate 210 may face each other. The first adhesive film 135 may be formed on the second adhesive film 235. The first and second adhesive films 135 and 235 may be attached together.

Isolation trenches 118t may be formed in the first substrate 110. The isolation trenches 118t may be deep trenches obtained by pattering the first substrate 110.

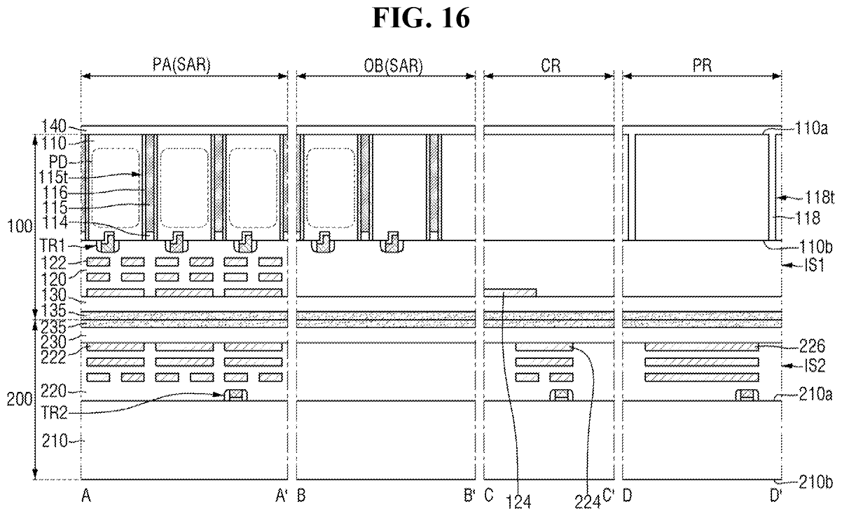

Referring to FIG. 16, a surface insulating film 140 may be formed on the first surface 110a of the first substrate 110.

The surface insulating film 140 may extend along the first surface 110a of the first substrate 110. Part of the surface insulating film 140 may fill the isolation trenches 118t. As a result, insulating patterns 118 may be formed in the isolation trenches 118t.

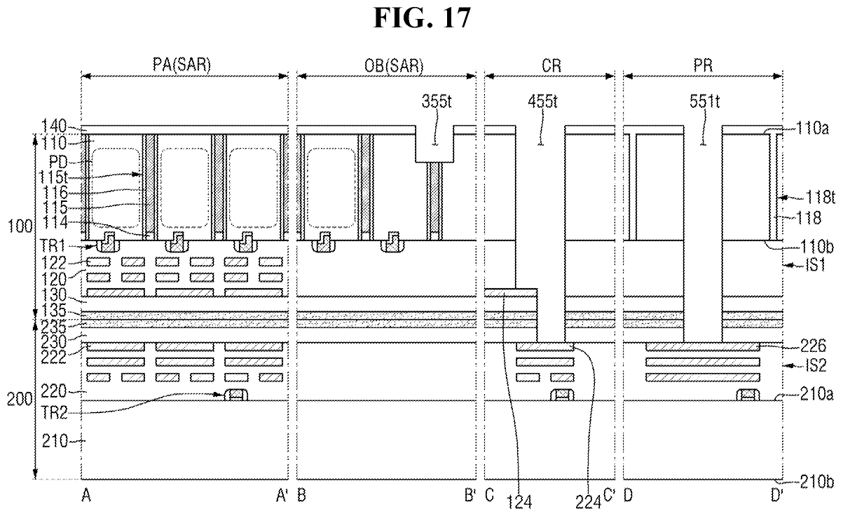

Referring to FIG. 17, a first via trench 551t may be formed in the surface insulating film 140. The first via trench 551t may extend from the first surface 110a of the first substrate 110 to expose the top surface of at least a portion of a fifth wiring 226.

A contact trench 355t may be formed in the surface insulating film 140. The contact trench 355t may be formed in the first substrate 110 in a light-blocking area OB. The contact trench 355t may extend from the first surface 110a of the first substrate 110. The contact trench 355t and the first via trench 551t may be formed at the same time or may be formed separately.

A connecting trench 455t may be formed in the surface insulating film 140. The connecting trench 455t may extend from the first surface 110a of the first substrate 110 in a connecting region CR, to expose the top surface of at least a portion of a second wiring 124 and the top surface of at least a portion of a fourth wiring 224. The connecting trench 455t and the first via trench 551t may be formed at the same time or may be formed separately.

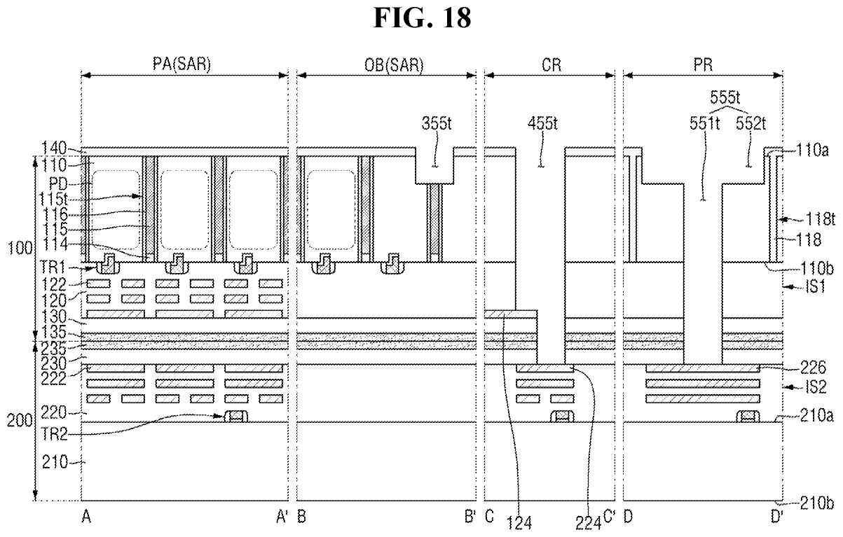

Referring to FIG. 18, a second via trench 552t may be formed in the first substrate 110 in a pad region PR. The second via trench 552t may extend from the first surface 110a of the first substrate 110 in the pad region PR. Accordingly, a via trench 555t, which includes the first and second via trenches 551t and 552t, may be formed. Alternatively, the contact trench 355t and the second via trench 552t may be formed at the same time. Alternatively, the first and second via trenches 551t and 552t may be formed separately from the contact trench 355t and the connecting trench 455t.

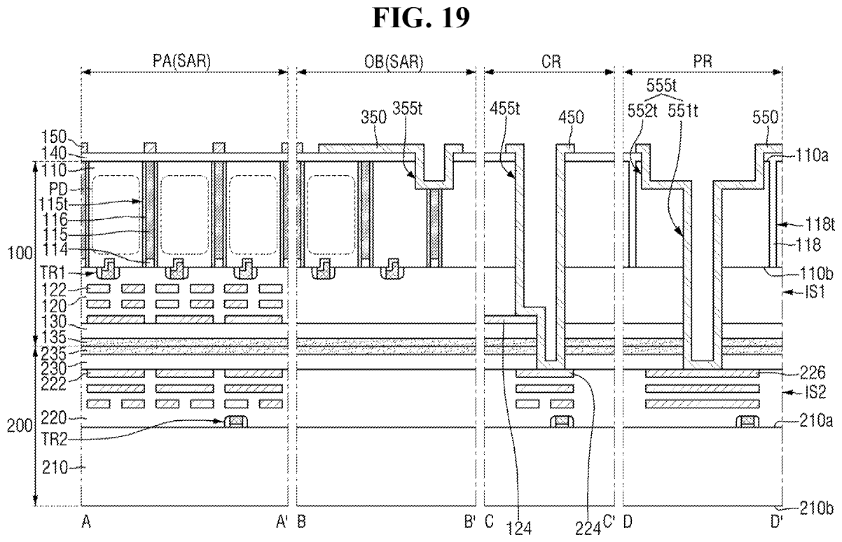

Referring to FIG. 19, a through via structure 550 may be formed in the via trench 555t. The through via structure 550 may extend along the via trench 555t. The through via structure 550 may contact the fifth wiring 226.

A contact film 350 may be formed in the contact trench 355t. The contact film 350 may extend along the contact trench 355t. The contact film 350 may contact the filling film 115. The contact film 350 and the through via structure 550 may be formed at the same time, but the present disclosure is not limited thereto.

A connecting structure 450 may be formed in the connecting trench 455t. The connecting structure 450 may extend along the connecting trench 455t. The connecting structure 450 may contact the second and fourth wirings 124 and 224. The connecting structure 450 and the through via structure 550 may be formed at the same time, but the present disclosure is not limited thereto.

Conductive patterns 150 may be formed in the pixel array area PA. The conductive patterns 150 may be formed on the surface insulating film 140, in the pixel array area PA.

Thereafter, referring to FIG. 4, low-refractive index patterns 160, a filling insulating film 460, the contact pattern 355, a first passivation film 165, color filters 170, light-blocking filters 170C, microlenses 180, a third passivation film 380, and a second passivation film 185 may be formed. As a result, the image sensor of FIG. 4 may be obtained.

Each of the embodiments provided in the above description is not excluded from being associated with one or more features of another example or another embodiment also provided herein or not provided herein but consistent with the disclosure.

At least one of the components, elements, modules or units (collectively “components” in this paragraph) represented by a block in the drawings may be embodied as various numbers of hardware, software and/or firmware structures that execute respective functions described above. At least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Functional aspects of the above example embodiments may be implemented in algorithms that execute on one or more processors. Furthermore, the components represented by a block or processing steps may employ any number of related art techniques for electronics configuration, signal processing and/or control, data processing and the like.

Although the disclosure been described in connection with some embodiments illustrated in the accompanying drawings, it will be understood by one of ordinary skill in the art that variations in form and detail may be made therein without departing from the spirit and essential feature of the disclosure. The above disclosed embodiments should thus be considered illustrative and not restrictive.

What is claimed is:

1. An image sensor comprising:
a first substrate comprising a first surface and a second surface opposite to the first surface;
a first wiring structure provided on the second surface of the first substrate, the first wiring structure comprising a first wiring and a first inter-wiring insulating film;
a second substrate comprising a third surface facing the second surface of the first substrate, and a fourth surface opposite to the third surface;
a second wiring structure provided on the third surface of the second substrate, the second wiring structure comprising a second wiring and a second inter-wiring insulating film;
a via trench penetrating the first substrate and the first wiring structure;
a through via structure extending along the via trench and connected to the second wiring; and
a pad pattern provided on the through via and filling at least a portion of the via trench.

2. The image sensor of claim 1, wherein the via trench comprises:
a first via trench having a first width, and
a second via trench, on the first via trench, having a second width greater than the first width.

3. The image sensor of claim 2, wherein the second via trench is provided in the first substrate.

4. The image sensor of claim 1, further comprising pixel isolation patterns provided in the first substrate, extending from the second surface of the first substrate to the first surface of the first substrate, and defining a plurality of unit pixels,
wherein the pixel isolation patterns do not overlap the through via structure in a direction from the second surface of the first substrate to the first surface of the first substrate.

5. The image sensor of claim 1, further comprising:
isolation trenches provided on at least one side of the via trench and extending from the first surface of the first substrate; and
insulating patterns filling the isolation trenches.

6. The image sensor of claim 5, wherein the isolation trenches extend from the first surface of the first substrate to the second surface of the first substrate.

7. The image sensor of claim 1, wherein the second inter-wiring insulating film comprises a plurality of wirings, and
wherein the second wiring is closest to the second surface of the first substrate from among the second wiring and the plurality of wirings of the second inter-wiring insulating film.

8. The image sensor of claim 1, wherein the second wiring structure comprises a third wiring, and
wherein the image sensor further comprises:
a connecting trench penetrating the first substrate and the first inter-wiring insulating film such that at least a portion of the first wiring and at least a portion of the third wiring are exposed, and
a connecting structure extending along the connecting trench and connecting the first wiring and the third wiring.

9. The image sensor of claim 8, further comprising a filling insulating film provided on the connecting structure and filling the connecting trench.

10. The image sensor of claim 8, wherein the connecting trench comprises:
a first connecting trench exposing at least a portion of the first wiring, and
a second connecting trench spaced apart from the first connecting trench and exposing at least a portion of the third wiring.

11. The image sensor of claim 1, wherein the first wiring structure further comprises first bonding patterns connected to the first wiring,
wherein the second wiring structure further comprises second bonding patterns connected to the second wiring, and
wherein the first bonding patterns and the second bonding patterns are connected.

12. An image sensor comprising:
a first substrate comprising a first surface and a second surface opposite to the first surface;
a first wiring structure provided on the second surface of the first substrate, the first wiring structure comprising a first wiring and a first inter-wiring insulating film;
a second substrate comprising a third surface facing the second surface, and a fourth surface opposite to the third surface;
a second wiring structure provided on the third surface of the second substrate, the second wiring structure comprising a second wiring and a second inter-wiring insulating film;
a pad pattern comprising:
a first portion provided in the first wiring structure and the first substrate, and
a second portion provided in the first substrate on the first portion, the second portion having a width greater than a width of the first portion; and
a through via structure extending from the first surface of the first substrate along at least a portion of the pad pattern and connected to the second wiring.

13. The image sensor of claim 12, wherein the through via structure extends along a bottom surface and sides of the pad pattern.

14. The image sensor of claim 12, wherein the second wiring structure further comprises a third wiring, and
wherein the image sensor further comprises a connecting structure extending from the first surface of the first substrate and connecting the first wiring and the third wiring.

15. The image sensor of claim 12, further comprising:
pixel isolation patterns provided in the first substrate, extending from the second surface of the first substrate to the first surface of the first substrate, and defining a plurality of unit pixels,
wherein the pixel isolation patterns do not overlap with the through via structure in a direction from the second surface of the first substrate to the first surface of the first substrate.

16. The image sensor of claim 12, wherein the first wiring structure further comprises first bonding patterns connected to the first wiring,
wherein the second wiring structure further comprises second bonding patterns connected to the second wiring, and
wherein the first bonding patterns are provided on the second bonding patterns.

17. The image sensor of claim 12, further comprising insulating patterns spaced apart from the through via structure and extending from the first surface of the first substrate.

18. An image sensor comprising a pixel array area, a light-blocking area around the pixel array area, and pad regions around the pixel array area, the image sensor comprising:
a first substrate comprising a first surface and a second surface opposite to the first surface;
pixel isolation patterns provided in the first substrate in the pixel array area and the light-blocking area, extending from the second surface, and defining a plurality of unit pixels;
a plurality of microlenses provided on the first surface of the first substrate and respectively corresponding to the plurality of unit pixels;
a first wiring structure provided on the second surface of the first substrate and comprising a first wiring and a first inter-wiring insulating film;
a second substrate comprising a third surface facing the second surface of the first substrate, and a fourth surface opposite to the third surface;
a second wiring structure provided on the third surface of the second substrate and comprising a second wiring and a second inter-wiring insulating film;
a via trench provided in the pad regions and penetrating the first substrate and the first wiring structure, in the pad regions, such that at least a portion of the second wiring is exposed;
a through via structure extending along the via trench;
a pad pattern provided in the via trench and on the through via structure; and
insulating patterns provided in the pad regions, spaced apart from the through via structure, and extending from the first surface of the first substrate.

19. The image sensor of claim 18, further comprising:
a contact pattern provided in the light-blocking area, and extending from the first surface of the first substrate, the contact pattern configured to be connected to the pixel isolation patterns;
a connecting region around the pixel array area; and
a connecting structure in the connecting region and penetrating the first substrate and the first wiring structure, connecting the first wiring and the second wiring.

20. The image sensor of claim 18, further comprising:
color filters provide on the first surface of the first substrate in the pixel array area; and
organic photoelectric conversion layers provided on the color filters.
